(19) United States
(12) Patent Application Publication
(10) Pub. No.: US 2024/0268242 A1
(43) Pub. Date: Aug. 8, 2024

(54) PHASE CHANGE STORAGE UNIT AND PHASE CHANGE MEMORY

(71) Applicant: Huawei Technologies Co., Ltd., Shenzhen (CN)

(72) Inventors: Xiang Li, Shanghai (CN); Yanrong Guo, Hangzhou (CN); Xin Chen, Hangzhou (CN); Ping Ma, Hangzhou (CN); Hao Tong, Wuhan (CN)

(21) Appl. No.: 18/602,721

(22) Filed: Mar. 12, 2024

Related U.S. Application Data
(63) Continuation of application No. PCT/CN2022/118183, filed on Sep. 9, 2022.

(30) Foreign Application Priority Data
Sep. 13, 2021 (CN) 202111068031.7
Jul. 21, 2022 (CN) 202210863735.1

(51) Int. Cl. H10N 70/00; H10B 63/10; H10N 70/20

(52) U.S. Cl. CPC H10N 70/8828; H10B 63/10; H10N 70/231

(57) ABSTRACT

This application provides a phase change material. The phase change material comprises a hafnium-containing material, the hafnium-containing material is formed by doping hafnium-containing or a hafnium-containing compound to a parent material, and the parent material comprises a compound that is formed by tellurium and at least one of germanium, antimony, and bismuth and that can perform a phase change.

### CROSS-REFERENCE TO RELATED APPLICATIONS

This application is a continuation of International Application No. PCT/CN2022/118183, filed on Sep. 9, 2022, which claims priority to Chinese Patent application Ser. No. 20/221,0863735.1, filed on Jul. 21, 2022, and Chinese patent application Ser. No. 20/2111068031.7, filed on Sep. 13, 2021. All of the aforementioned patent applications are hereby incorporated by reference in their entireties.

### TECHNICAL FIELD

This application relates to the field of storage technologies, and in particular, to a phase change storage unit and a phase change memory.

### BACKGROUND

With the wide application of technologies such as mobile Internet, cloud computing, big data, deep learning, and Internet of Things, the market has a growing demand for ultra-high density and ultra-large capacity data storage. A phase change memory (PCM), as one of the most promising non-volatile storage technologies for application, has been used in a plurality of storage structure directions. For example, in a two-dimensional memory structure direction, a two-dimensional phase change memory has been used in an embedded application. For another example, in a three-dimensional memory structure direction, a three-dimensional phase change memory, as a storage class memory, has been used in a scenario such as a data center.

The phase change memory has advantages such as low power consumption, high density, and a small size, and implements data reading and writing through a conductivity difference shown when a phase change material changes between a crystalline state and an amorphous state in an electrical pulse manner. Currently, in the phase change memory, the phase change material is mainly a material of GeₓSb_{y}Te_{1-x-y}. Because a nucleation center of the material of GeₓSb_{y}Te_{1-x-y} in the amorphous state is unstable, a nucleation step in a crystallization process is slow, and a SET operation speed is slow. In addition, a density difference of the material of GeₓSb_{y}Te_{1-x-y} in the crystalline state and the amorphous state is large, a material volume changes repeatedly in a cyclic operation process, and it is easy to cause generation of a void. As a result, cycling performance is poor.

### SUMMARY

This application provides a phase change storage unit and a phase change memory, so as to improve a SET operation speed of the phase change memory and improve cycling performance of the phase change memory.

According to a first aspect, this application provides a phase change storage unit, where the phase change storage unit includes a first electrode, a second electrode, and a phase change material layer. The phase change material layer is located between the first electrode and the second electrode, the phase change material layer includes a parent phase change material doped with a hafnium (Hf) metal and/or a hafnium compound, and the parent phase change material is a material including at least one of elements of germanium (Ge), antimony (Sb), tellurium (Te), and bismuth (Bi).

In the phase change storage unit provided in this application, the phase change material layer includes the parent phase change material doped with the hafnium metal and/or the hafnium compound, and the hafnium metal and/or the hafnium compound may be used as a crystal nucleus in a crystallization process, to accelerate a crystallization process of the phase change material layer, thereby improving a SET operation speed. In addition, the doped hafnium metal and/or hafnium compound may fill a vacancy when the parent phase change material is in a crystalline state, to reduce a volume change of the phase change material layer before and after a phase change, thereby reducing generation of a void and improving cycling performance.

In a possible implementation of this application, an atomic percentage of the hafnium metal and/or the hafnium compound in the phase change material layer is 0.1% to 40%. In this implementation, the atomic percentage of the hafnium metal and/or the hafnium compound in the phase change material layer is 0.1% to 40%, so that a crystallization speed of the phase change material layer can be increased, and the cycling performance can be improved.

The following provides several examples of the atomic percentage of the hafnium metal and/or the hafnium compound in the phase change material layer:

Example 1: The atomic percentage of the hafnium metal and/or the hafnium compound in the phase change material layer is 1.5% to 6.5%.

Example 2: The atomic percentage of the hafnium metal and/or the hafnium compound in the phase change material layer is 10% to 19.5%.

Example 3: The atomic percentage of the hafnium metal and/or the hafnium compound in the phase change material layer is 25% to 35%.

All the three examples can improve the crystallization speed of the phase change material layer and improve the cycling performance. The crystallization speed is sequentially Example 3, Example 2, and Example 1 in ascending order, and a quantity of cycles is sequentially Example 1, Example 2, and Example 3 in ascending order. Generally, a higher crystallization speed indicates better performance of the phase change material layer, and a higher quantity of cycles indicates better performance of the phase change material layer. Therefore, the performance of the phase change material layer in the three examples has respective advantages and disadvantages.

In a possible implementation of this application, the parent phase change material includes any one of the following materials: GeₓSb_{y}Te_{1-x-y} and GeₓBi_{y}Te_{1-x-y}, where a value range of a sum of x and y is 0 to 100%.

In a possible implementation of this application, the hafnium compound includes at least one of the following: a hafnium metal oxide, a hafnium metal boride, a hafnium metal carbide, a hafnium metal nitrogen compound, a hafnium metal sulfur compound, a hafnium metal halogen compound, and a binary or multi-ary compound formed by a hafnium metal and another metal.

In a possible implementation of this application, the phase change storage unit may further include a gating material layer, and the gating material layer is located between the first electrode and the second electrode. A specific disposition location of the gating material layer is not limited in this application. The gating material layer may be in a high resistance state at a low voltage, so as to suppress a leakage current, and may be in a low resistance state at a high voltage, so as to provide a sufficient current for read and write operations.

In a possible implementation of this application, the phase change storage unit may further include at least one of the following layers located between the first electrode and the second electrode: an insulation layer, a heating layer, an adhesion layer, and a buffer layer.

When the insulation layer is specifically disposed, the insulation layer may wrap an exposed surface of the phase change material layer, and the insulation layer is non-conductive. In this case, a current passes through the phase change material layer in a centralized manner, so that current density and current heating efficiency can be improved. A specific disposition location of the insulation layer is not limited in this application.

When the heating layer is specifically disposed, the heating layer may be disposed between any two layers between the first electrode and the second electrode. For example, the heating layer is disposed between the first electrode and the phase change material layer. For another example, the heating layer is disposed between the phase change material layer and the second electrode. A specific disposition location of the heating layer is not limited in this application. The heating layer can improve a resistance of the entire unit, thereby improving the heating efficiency of the unit current.

When the adhesion layer is specifically disposed, the adhesion layer may be disposed between any two layers between the first electrode and the second electrode. A specific disposition location of the adhesion layer is not limited in this application. The adhesion layer can improve an adhesion effect between two layers adjacent to the adhesion layer.

When the buffer layer is specifically disposed, the buffer layer may be disposed between any two layers between the first electrode and the second electrode. A specific disposition location of the buffer layer is not limited in this application. The buffer layer can reduce mutual diffusion of two adjacent material layers in the phase change storage unit in repeated erase and write (or reset/set) operations, thereby improving reliability.

In a possible implementation of this application, the phase change material layer is prepared by using a chemical vapor deposition method, physical vapor deposition, or atomic layer deposition.

According to a second aspect, this application provides another phase change storage unit, where the phase change storage unit includes a first electrode, a second electrode, and a phase change material layer. The phase change material layer is located between the first electrode and the second electrode, the phase change material layer includes at least one hafnium-containing material layer and at least one sulfur compound material layer that are laminated, the hafnium-containing material layer includes at least one of the following materials: a hafnium (Hf) metal, a hafnium compound, a parent phase change material doped with the hafnium metal and/or the hafnium compound, and the parent phase change material is a material including at least one of elements of germanium (Ge), antimony (Sb), tellurium (Te), and bismuth (Bi).

In the phase change storage unit provided in this application, the phase change material layer includes the at least one hafnium-containing material layer and the at least one sulfur compound material layer that are laminated, and the doped hafnium metal and/or hafnium compound included in the hafnium-containing material layer may be used as a crystal nucleus in a crystallization process, to accelerate a crystallization process, thereby improving a SET operation speed. In addition, the phase change material layer includes at least two layers of laminated structures, so that thermal conductivity of the phase change storage unit is changed, and an interface between the two material layers hinders heat conduction. Therefore, heating efficiency can be improved, and power consumption of a RESET operation can be reduced, thereby reducing a probability of generating a void, and improving cycling performance. In addition, the sulfur compound material layer further helps to suppress a low-resistance failure caused by conduction between upper and lower electrodes caused by element segregation in the hafnium-containing material layer, thereby improving the cycling performance of the phase change storage unit, and helping reduce a resistance drift.

In a possible implementation of this application, the sulfur compound material layer includes at least one of the following materials: a tellurium compound of a tellurium (Te) element and at least one of elements of germanium (Ge), antimony (Sb), titanium (Ti), tantalum

(Ta), scandium (Sc), bismuth (Bi), silicon (Si), carbon (C), platinum (Pt), and indium (In) and a tellurium compound doped with a hafnium metal and/or a hafnium compound.

In a possible implementation of this application, the parent phase change material includes any one of the following materials: GeₓSb_{y}Te_{1-x-y}, GeₓBi_{y}Te_{1-x-y}, and SbₓTe_{y}, where a value range of a sum of x and y is 0 to 100%.

In a possible implementation of this application, the hafnium-containing material layer and the sulfur compound material layer that are included in the phase change material layer are alternately arranged. In this manner, if an element segregation problem occurs in a hafnium-containing material layer, and the hafnium-containing material layer is conducted, a simple substance precipitated from the hafnium-containing material layer may be combined with a material in a sulfur compound material layer adjacent to the hafnium-containing material layer, so that the low-resistance failure caused by conduction of the entire phase change material layer can be effectively suppressed, thereby improving the cycling performance of the phase change storage unit, and reducing the resistance drift.

In a possible implementation of this application, the phase change material layer includes at least three material layers that are laminated, the at least three material layers include at least one hafnium-containing material layer and at least one sulfur compound material layer, and the hafnium-containing material layer and the sulfur compound material layer that are included in the at least three material layers are alternately arranged. In this manner, a quantity of interfaces in the phase change material layer can be increased, and the thermal conductivity can be further reduced. Therefore, the heating efficiency can be improved, and the power consumption of the RESET operation can be reduced, thereby reducing the probability of generating a void and further improving the cycling performance.

In a possible implementation of this application, the phase change storage unit further includes a gating material layer located between the first electrode and the second electrode. A specific disposition location of the gating material layer is not limited in this application. The gating material layer may be in a high resistance state at a low voltage, so as to suppress a leakage current, and may be in a low resistance state at a high voltage, so as to provide a sufficient current for read and write operations.

In a possible implementation of this application, the phase change storage unit may further include at least one of the following layers located between the first electrode and the second electrode: an insulation layer, an electrode layer, a heating layer, an adhesion layer, and a buffer layer.

When the insulation layer is specifically disposed, the insulation layer may wrap an exposed surface of the phase change material layer, and the insulation layer is non-conductive. In this case, a current passes through the phase change material layer in a centralized manner, so that current density and current heating efficiency can be improved. A specific disposition location of the insulation layer is not limited in this application.

When the electrode layer is specifically disposed, the electrode layer may be disposed between any two layers between the first electrode and the second electrode. A specific disposition location of the electrode layer is not limited in this application.

When the heating layer is specifically disposed, the heating layer may be disposed between any two layers between the first electrode and the second electrode. For example, the heating layer is disposed between the first electrode and the phase change material layer. For another example, the heating layer is disposed between the phase change material layer and the second electrode. A specific disposition location of the heating layer is not limited in this application. The heating layer can improve a resistance of the entire unit, thereby improving the heating efficiency of the unit current.

When the adhesion layer is specifically disposed, the adhesion layer may be disposed between any two layers between the first electrode and the second electrode. A specific disposition location of the adhesion layer is not limited in this application. The adhesion layer can improve an adhesion effect between two layers adjacent to the adhesion layer.

When the buffer layer is specifically disposed, the buffer layer may be disposed between any two layers between the first electrode and the second electrode. A specific disposition location of the buffer layer is not limited in this application. The buffer layer can reduce mutual diffusion of two adjacent material layers in the phase change storage unit in repeated erase and write (or reset/set) operations, thereby improving reliability.

In a possible implementation of this application, the phase change material layer is prepared by using a chemical vapor deposition method, a physical vapor deposition method, or an atomic layer deposition method.

According to a third aspect, this application provides a phase change memory, including a controller and a storage medium, where the storage medium includes an array including the phase change storage unit in the first aspect and the possible implementations of the first aspect, or an array including the phase change storage unit in the second aspect and the possible implementations of the second aspect.

### BRIEF DESCRIPTION OF THE DRAWINGS

FIG. 1A is a schematic diagram of a structure of a phase change storage unit according to an embodiment of this application;

FIG. 1B is another schematic diagram of a structure of a phase change storage unit according to an embodiment of this application;

FIG. 2 is a schematic diagram of a vertical cross section of a phase change material layer 13 including one material layer according to an embodiment of this application;

FIG. 3 is a schematic diagram of a vertical cross section of a phase change material layer 13 including two material layers according to an embodiment of this application;

FIG. 4 is another schematic diagram of a vertical section of a phase change material layer 13 including two material layers according to an embodiment of this application;

FIG. 5 is another schematic diagram of a vertical section of a phase change material layer 13 including two material layers according to an embodiment of this application;

FIG. 6 is another schematic diagram of a vertical section of a phase change material layer 13 including two material layers according to an embodiment of this application;

FIG. 7 is a schematic diagram of a vertical cross section of a phase change material layer 13 including at least three material layers according to an embodiment of this application;

FIG. 8 is another schematic diagram of a vertical cross section of a phase change material layer 13 including at least three material layers according to an embodiment of this application;

FIG. 9 is another schematic diagram of a vertical cross section of a phase change material layer 13 including at least three material layers according to an embodiment of this application;

FIG. 10 is another schematic diagram of a vertical cross section of a phase change material layer 13 including at least three material layers according to an embodiment of this application;

FIG. 11 is another schematic diagram of a structure of a phase change storage unit according to an embodiment of this application;

FIG. 12 is another schematic diagram of a structure of a phase change storage unit according to an embodiment of this application;

FIG. 13 is another schematic diagram of a structure of a phase change storage unit according to an embodiment of this application;

FIG. 14 is a schematic diagram of a structure of a phase change memory according to an embodiment of this application;

FIG. 15 is another schematic diagram of a structure of a phase change memory according to an embodiment of this application; and

FIG. 16 is a schematic diagram of value ranges of x and y in GeₓSb_{y}Te_{1-x-y} according to an embodiment of this application.

### ICON DESCRIPTION

1—phase change storage unit;

11—first electrode;

12—second electrode;

13—phase change material layer;

131—hafnium-containing material layer;

132—sulfur compound material layer;

14—gating material layer;

15—insulation layer;

16—heating layer;

17—first electrode layer;

18—second electrode layer;

19—third electrode layer;

2—first electrode line; and

3—second electrode line.

### DETAILED DESCRIPTION OF ILLUSTRATIVE EMBODIMENTS

Terms used in the following embodiments are merely intended to describe specific embodiments, and are not intended to limit this application. As used in the specification and the appended claims of this application, the singular expressions “a/an”, “one”, “said”, “the above”, “the” and “this” are intended to also include such expressions as “one or more”, unless otherwise clearly indicated in the context.

Reference to “an embodiment”, “some embodiments”, or the like described in the specification of this application indicates that one or more embodiments of this application include a specific feature, structure, or characteristic described with reference to embodiments. Therefore, statements “in an embodiment”, “in some embodiments”, “in some other embodiments”, “in other embodiments”, and the like that appear at different places in this specification do not necessarily refer to a same embodiment. Instead, the statements mean “one or more but not all of embodiments”, unless otherwise specifically emphasized in another manner. The terms “include”, “comprise”, “have”, and variations thereof all mean “including, but not limited to”, unless otherwise particularly specified.

To facilitate understanding of a phase change storage unit and a phase change memory that are provided in embodiments of this application, the following describes application scenarios of the phase change storage unit and the phase change memory. The phase change memory provided in this application may be configured to store data in an electronic device such as a mobile phone, a tablet computer, a notebook computer, a wearable device, or an in-vehicle device. The phase change memory is a non-volatile memory based on a sulfur phase change material, and can be converted in different resistance states in a heat action. Data 0 and data 1 are stored by using a difference of 10 to 10000 times a resistance value between a high resistance state (a reset state) and a low resistance state (a set state) of the phase change memory. A set operation is an operation from the high resistance state to the low resistance state, and a reset operation is an operation from the low resistance state to the high resistance state.

Currently, in the phase change memory, a phase change material is mainly a material of GeₓSb_{y}Te_{1-x-y}. Because a nucleation center of the material of GeₓSb_{y}Te_{1-x-y} in an amorphous state is unstable, a nucleation step in a crystallization process is slow, and a SET operation speed is slow. In addition, a density difference of the material of GeₓSb_{y}Te_{1-x-y} in a crystalline state and the amorphous state is large, a material volume changes repeatedly in a cyclic operation process, and it is easy to cause generation of a void. As a result, cycling performance is poor. To resolve the foregoing problem, this application provides a phase change storage unit and a phase change memory. The following describes the phase change storage unit and the phase change memory in the technical solutions of this application with reference to the accompanying drawings.

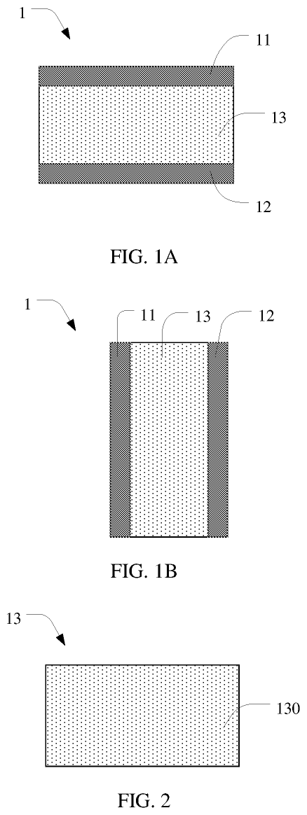

FIG. 1A is a schematic diagram of a structure of a phase change storage unit according to an embodiment of this application. As shown in FIG. 1A, a phase change storage unit 1 in this embodiment of this application includes a first electrode 11, a second electrode 12, and a phase change material layer 13. The phase change material layer 13 is located between the first electrode 11 and the second electrode 12.

It should be noted that the first electrode 11 and the second electrode 12 in this embodiment of this application may be in an up-down structure shown in FIG. 1A. In other words, the first electrode 11 is above the second electrode 12 in a vertical direction. It should be understood that in some other embodiments, the first electrode 11 may alternatively be below the second electrode 12 in the vertical direction. This is not limited in this embodiment of this application. In some other embodiments, the first electrode 11 and the second electrode 12 may 12 may be in a left-right structure shown in FIG. 1B. In other words, the first electrode 11 is on the left of the second electrode 12 in a horizontal direction. It should be understood that in some other embodiments, the first electrode 11 may alternatively be on the right of the second electrode 12 in the horizontal direction. This is not limited in this embodiment of this application. Similarly, the first electrode 11 and the second electrode 12 in FIG. 11, FIG. 13, and FIG. 13 below may be the up-down structure in the vertical direction or the left-right structure in the vertical direction. Details are not described in the following.

For ease of description, in the following embodiments, the first electrode 11 and the second electrode 12 are schematically described by using the up-down structure in the vertical direction. Details are not described in the following.

The phase change material layer 13 has a first resistance state and a second resistance state, and a resistance value of the phase change material layer 13 in the first resistance state is different from a resistance value of the phase change material layer 13 in the second resistance state, so that read and write operations may be performed by controlling and reading a current resistance value of the phase change storage unit 1. It should be understood that the phase change material layer 13 may have more than two resistance states, and may have a plurality of resistance states. A quantity of resistance states of the phase change material layer 13 is not limited in this application.

In this embodiment of this application, the phase change material layer 13 may have a plurality of possible implementations, which are separately described below.

In a possible implementation 1, the phase change material layer 13 includes one material layer.

FIG. 2 is a schematic diagram of a vertical cross section of a phase change material layer 13 including one material layer according to an embodiment of this application. As shown in FIG. 2, the phase change material layer 13 includes one material layer 130, where the material layer 130 includes a parent phase change material 130 doped with a hafnium (Hf) metal and/or a hafnium compound, and the parent phase change material is a material including at least one of elements of germanium (Ge), antimony (Sb), tellurium (Te), and bismuth (Bi). A local crystalline structure of the hafnium metal and/or the hafnium compound is consistent with a local crystalline structure of a matrix material. In the implementation 1, the phase change material layer 13 includes the parent phase change material doped with the hafnium metal

For ease of description, in the following embodiments, the first electrode 11 and the second electrode 12 are schematically described by using the up-down structure in the vertical direction. Details are not described in the following. change material is in a crystalline state, to reduce a volume change of the phase change material layer 13 before and after a phase change, thereby reducing generation of a void and improving cycling performance.

In an embodiment of this application, atomic percentages of different parts of the hafnium-containing or the hafnium-containing compound in the phase change material are inconsistent. For example, when the phase change material is located between a top electrode and a bottom electrode, the atomic percentages of the hafnium-containing or the hafnium-containing compound in the phase change material are in a gradient change from high to low or from low to high in a direction from the top electrode to the bottom electrode.

In this embodiment of this application, an atomic percentage of the hafnium metal and/or the hafnium compound in the phase change material layer 13 is 0.1% to 40%. The atomic percentage of the hafnium metal and/or the hafnium compound is set in this way, so that a crystallization speed of the phase change material layer can be improved, and the cycling performance can be improved.

The following provides several examples of the atomic percentage of the hafnium metal and/or the hafnium compound in the phase change material layer:

Example 1: The atomic percentage of the hafnium metal and/or the hafnium compound in the phase change material layer 13 is 1.5% to 6.5%.

Example 2: The atomic percentage of the hafnium metal and/or the hafnium compound in the phase change material layer 13 is 10% to 19.5%.

Example 3: The atomic percentage of the hafnium metal and/or the hafnium compound in the phase change material layer 13 is 25% to 35%.

Example 4: The atomic percentage of the hafnium metal and/or the hafnium compound in the phase change material layer 13 is 7% to 14%.

Example 5: The atomic percentage of the hafnium metal and/or the hafnium compound in the phase change material layer 13 is 17% to 24%.

Example 6: The atomic percentage of the hafnium metal and/or the hafnium compound in the phase change material layer 13 is 27% to 34%.

All the six examples can improve the crystallization speed of the phase change material layer 13 and improve the cycling performance. The crystallization speed is sequentially Example 3, Example 2, and Example 1 in ascending order, and a quantity of cycles is sequentially Example 1, Example 2, and Example 3 in ascending order. Generally, a higher crystallization speed indicates better performance of the phase change material layer, and a higher quantity of cycles indicates better performance of the phase change material layer. Therefore, the performance of the phase change material layer in the three examples has respective advantages and disadvantages.

In an embodiment of this application, a specific material of the parent phase change material is not limited, and the parent phase change material may include any one of the following materials: GeₓSb_{y}Te_{1-x-y}, GeₓBi_{y}Te_{1-x-y}, SbₓTe_{y}, BiₓTe_{y}, GeₓTe_{y}, and Sb, where a value range of a sum of x and y is 0 to 100%. The parent phase change material may further include GeₓSb_{y}Bi_{z}Te_{1-x-y-z}, where a value range of a sum of x, y, and z is 0 to 100%.

For example, the parent phase change material is, for example, any one of GeₓSb_{y}Te_{1-x-y} and GeₓBi_{y}Te_{1-x-y}, where a value range of a sum of x and y is 0 to 100%.

For another example, the parent material may be SbₓTe_{y}, or the parent material further includes GeₓSb_{y}Bi_{z}Te_{1-x-y-z}, where a sum of x, y, and z is 100%.

In the materials GeₓSb_{y}Te_{1-x-y} and GeₓBi_{y}Te_{1-x-y}, x:y:(1−x−y)=4:1:5, 2:2:5, 3:2:6, 1:2:4, or 1:4:7, and in the material SbₓTe_{y}, x:y=2:3, 1:1, 2:1, or 1:0.

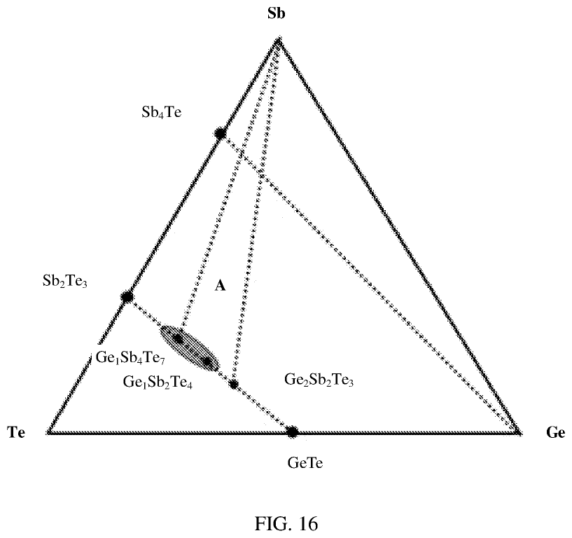

In another example, a value range of a concentration of GeₓSb_{y}Te_{1-x-y} may be a gray elliptic region and a quadrilateral region A shown in FIG. 16. The material GeₓSb_{y}Te_{1-x-y} in the region has a high-speed crystallization characteristic, and also has specific thermal stability. In the black elliptic region, 1/7−1/10≤x:(1−x−y)≤1/4+1/10 or 2/3−1/10≤y:(1−x−y)≤2/3+1/10, and in the quadrilateral region A, 1/7≤x:(1−x−y)≤2/5 and 2/3≤y:(1−x−y)≤4. In an embodiment of this application, a specific material of the hafnium compound is not limited. The hafnium compound may include at least one of the following: a hafnium metal oxide (for example, HfO₂), a hafnium metal boride (for example, HfB), a hafnium metal carbide (for example, HfC), a hafnium metal nitride compound (for example, HfN), a hafnium metal sulfur compound (for example, HfS, HfSe, and HfTe), a hafnium metal halogen compound (for example, HfF, HfCl, and HfBr), and a binary or multi-ary compound (for example, HfTa, HfW, HfTi, and HfSc) formed by a hafnium metal and another metal.

In an embodiment of this application, the phase change material layer 13 may be prepared by using a deposition method. For example, the deposition method may be a chemical vapor deposition (CVD) method, a physical vapor deposition (PVD) method, or an atomic layer deposition (ALD) method.

For example, in the physical vapor deposition method, two or more targets may be used. One target is an Hf-containing material, and the other target is a parent phase change material, or may be an alloy target. The alloy target includes both the Hf-containing material and the parent material. In a deposition process, N₂, O₂, and the like may be further added to form a nitride or oxide.

In a possible implementation 2, the phase change material layer 13 includes a plurality of material layers.

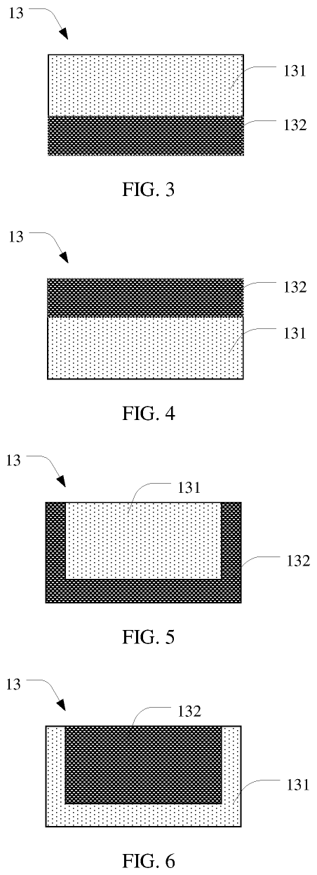

FIG. 3 to FIG. 10 are schematic diagrams of vertical cross sections of a phase change material layer 13 including a plurality of material layers according to an embodiment of this application.

As shown in FIG. 3 to FIG. 10, the phase change material layer 13 includes at least one hafnium-containing material layer 131 and at least one sulfur compound material layer 132 that are laminated. The hafnium-containing material layer 131 includes at least one of the following materials: a hafnium (Hf) metal, a hafnium compound, a parent phase change material doped with the hafnium metal and/or the hafnium compound, and the parent phase change material is a material of at least one of elements of germanium (Ge), antimony (Sb), tellurium (Te), and bismuth (Bi). In the implementation 2, the phase change material layer 13 includes the at least one hafnium-containing material layer 131 and the at least one sulfur compound material layer 132 that are laminated, and the doped hafnium metal and/or hafnium compound included in the hafnium-containing material layer 131 may be used as a crystal nucleus in a crystallization process, to accelerate a crystallization process, thereby improving a SET operation speed. In addition, the phase change material layer 13 includes at least two layers of laminated structures, so that thermal conductivity of the phase change storage unit is changed, and an interface between the two material layers hinders heat conduction. Therefore, heating efficiency can be improved, and power consumption of a RESET operation can be reduced, thereby reducing a probability of generating a void, and improving cycling performance. In addition, the sulfur compound material layer 132 further helps to suppress a low-resistance failure caused by conduction between upper and lower electrodes caused by element segregation in the hafnium-containing material layer 131, thereby improving the cycling performance of the phase change storage unit, and helping reduce a resistance drift.

In an embodiment of this application, the sulfur compound material layer 132 may include at least one of the following materials: a tellurium compound of a tellurium (Te) element and at least one of elements of germanium (Ge), antimony (Sb), titanium (Ti), tantalum (Ta), scandium (Sc), bismuth (Bi), silicon (Si), carbon (C), platinum (Pt), and indium (In), and a tellurium compound doped with a hafnium metal and/or a hafnium compound.

For example, the sulfur compound material layer 132 may be GeₓTe₁₋ₓ, SbₓTe₁₋ₓ, GeₓTe₁₋ₓ, TiₓTe₁₋ₓ, TaₓTe₁₋ₓ, ScₓTe₁₋ₓ, BiₓTe₁₋ₓ, GeₓSb₁₋ₓ, InₓTe₁₋ₓ, SiₓTe₁₋ₓ, CₓTe₁₋ₓ, PtₓTe₁₋ₓ, GeₓSb_{y}Te_{1-x-y}, GeₓBi_{y}Te_{1-x-y}, TaₓSb_{y}Te_{1-x-y}, TiₓSb_{y}Te_{1-x-y}, or ScₓSb_{y}Te_{1-x-y}, or may be an Hf- containing sulfur compound, for example, HfₓTe₁₋ₓ, HfₓSb_{y}Te_{1-x-y}, or HfGeₓSb_{y}Te_{1-x-y}, or an Hf-containing material in which a concentration of a hafnium atom is different from a concentration of a hafnium atom in the parent phase change material doped with the hafnium (Hf) metal and/or the hafnium compound in the implementation 1 (which may also be understood as an atomic percentage occupied by the hafnium atom in the parent phase change material doped with the hafnium (Hf) metal and/or the hafnium compound). A value range of a sum of x and y is 0 to 100%.

In an embodiment of this application, a specific material of the parent phase change material is not limited, and the parent phase change material may include any one of the following materials: GeₓSb_{y}Te_{1-x-y}, GeₓBi_{y}Te_{1-x-y}, SbₓTe_{y}, BiₓTe₁, GeₓTe_{y}, and Sb, where a value range of a sum of x and y is 0 to 100%. The parent phase change material may further include GeₓSb_{y}Bi_{z}Te_{1-x-y-z}, where a value range of a sum of x, y, and z is 0 to 100%.

For example, the parent phase change material is, for example, any one of GeₓSb_{y}Te_{1-x-y} and GeₓBi_{y}Te_{1-x-y}.

In an embodiment of this application, a specific material of the hafnium compound is not limited. The hafnium compound may include at least one of the following: a hafnium metal oxide (for example, HfO₂), a hafnium metal boride (for example, HfB), a hafnium metal carbide (for example, HfC), a hafnium metal nitride compound (for example, HfN), a hafnium metal sulfur compound (for example, HfS, HfSe, and HfTe), a hafnium metal halogen compound (for example, HfF, HfCl, and HfBr), and a binary or multi-ary compound (for example, HfTa, HfW, HfTi, and HfSc) formed by a hafnium metal and another metal.

In an example, a material combination of the hafnium-containing material layer 131 and the sulfur compound material layer 132 may be, for example, any one of the following: HfGeₓSb_{y}Te_{1-x-y}/SbₓTe₁₋ₓ, HfGeₓSb_{y}Te_{1-x-y}/GeₓSb_{y}Te_{1-x-y}, HfGeₓSb_{y}Te_{1-x-y}/GeₓTe₁₋ₓ, HfGeₓSb_{y}Te_{1-x-y} (a concentration A)/HfGeₓSb_{y}Te_{1-x-y} (a concentration B), where the concentration A is different from the concentration B, HfO₂/HfGeₓSb_{y}Te_{1-x-y}, and HfₓTe_{1-x-y}/HfGeₓSb_{y}Te_{1-x-y}, and the like.

In an embodiment of this application, the hafnium-containing material layer 131 and the sulfur compound material layer 132 that are included in the phase change material layer 13 are alternately arranged. In this manner, if an element segregation problem occurs in a hafnium-containing material layer 131, and the hafnium-containing material layer 131 is conducted, a simple substance precipitated from the hafnium-containing material layer 131 may be combined with a material in a sulfur compound material layer 132 adjacent to the hafnium-containing material layer 131, so that the low-resistance failure caused by conduction of the entire phase change material layer 13 can be effectively suppressed, thereby improving the cycling performance of the phase change storage unit, and reducing the resistance drift.

Still refer to FIG. 3 to FIG. 6. The phase change material layer 13 includes a hafnium-containing material layer 131 and a sulfur compound material layer 132. As shown in FIG. 3, the sulfur compound material layer 132 may be located below the hafnium-containing material layer 131. It may be understood that, in the phase change storage unit, the sulfur compound material layer 132 is located on a side that is of the hafnium-containing material layer 131 and that is away from the first electrode 11. As shown in FIG. 4, the sulfur compound material layer 132 may alternatively be located above the hafnium-containing material layer 131. It may be understood that in the phase change storage unit, the sulfur compound material layer 132 is located on a side that is of the hafnium-containing material layer 131 and that is away from the second electrode 12. As shown in FIG. 5, the sulfur compound material layer 132 may alternatively be located below the hafnium-containing material layer 131, and the sulfur compound material layer 132 wraps a side wall and a bottom of the hafnium-containing material layer 131. As shown in FIG. 6, the sulfur compound material layer 132 may alternatively be located above the hafnium-containing material layer 131, and the hafnium-containing material layer 131 wraps a side wall and a bottom of the sulfur compound material layer 132.

In an embodiment of this application, the phase change material layer 13 includes at least three material layers that are laminated, the at least three material layers include at least one hafnium-containing material layer 131 and at least one sulfur compound material layer 132, and the hafnium-containing material layer 131 and the sulfur compound material layer 132 that are included in the at least three material layers are alternately arranged. In this manner, a quantity of interfaces in the phase change material layer 13 can be increased, and the thermal conductivity can be further reduced. Therefore, the heating efficiency can be improved, and the power consumption of the RESET operation can be reduced, thereby reducing the probability of generating a void and further improving the cycling performance.

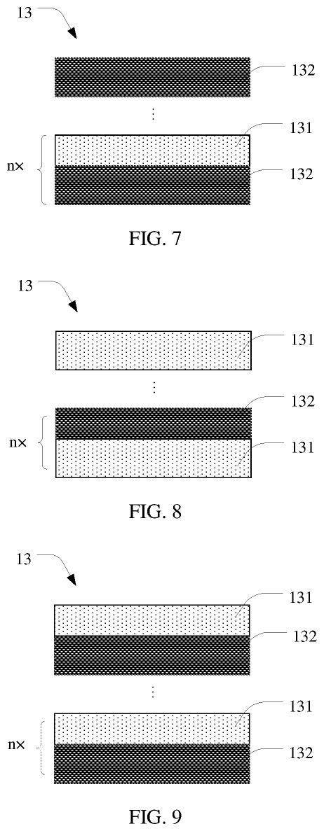

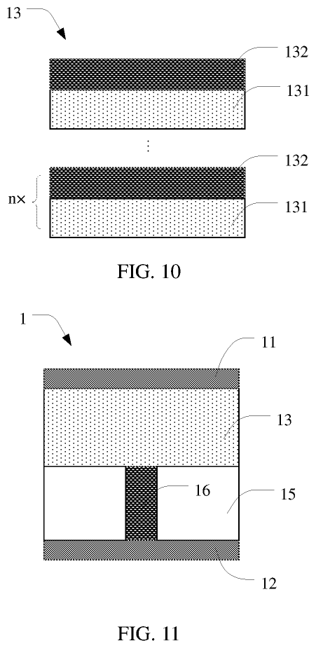

Still refer to FIG. 7 to FIG. 10. The phase change material layer 13 includes three or more material layers, and a dual-layer material layer including the hafnium-containing material layer 131 and the sulfur compound material layer 132, as a basic unit, is repeated n times, where n is an integer greater than or equal to 1. As shown in FIG. 7, both an uppermost layer and a lowermost layer of the phase change material layer 13 are the sulfur compound material layers 132. As shown in FIG. 8, both an uppermost layer and a lowermost layer of the phase change material layer 13 are the hafnium-containing material layers 131. As shown in FIG. 9, an uppermost layer of the phase change material layer 13 is the hafnium-containing material layer 131, and a lowermost layer of the phase change material layer 13 is the sulfur compound material layer 132. As shown in FIG. 10, an uppermost layer of the phase change material layer 13 is the sulfur compound material layer 132, and a lowermost layer of the phase change material layer 13 is the hafnium-containing material layer 131.

In an embodiment of this application, the at least one hafnium-containing material layer 131 and the at least one sulfur compound material layer 132 included in the phase change material layer 13 may be prepared by using a deposition method. For example, the deposition method may be a chemical vapor deposition method, a physical vapor deposition method, or an atomic layer deposition method.

Based on the implementation 1 and the implementation 2, in an embodiment of this application, the phase change storage unit may further include at least one of the following layers located between the first electrode 11 and the second electrode 12: an insulation layer, a heating layer, an adhesion layer, a buffer layer, and an electrode layer.

When the insulation layer is specifically disposed, the insulation layer may wrap an exposed surface of the phase change material layer 13, and the insulation layer is non-conductive. In this case, a current passes through the phase change material layer 13 in a centralized manner, so that current density and current heating efficiency can be improved. A specific disposition location of the insulation layer is not limited in this application. A material of the insulation layer may be, for example, at least one of silicon dioxide (SiO₂), silicon nitride (SiN), or titanium nitride (TiN), or may be another material that can isolate a current. A specific material of the insulation layer is not limited in this application.

When the heating layer is specifically disposed, the heating layer may be disposed between any two layers between the first electrode 11 and the second electrode 12. For example, the heating layer is disposed between the first electrode 11 and the phase change material layer 13. For another example, the heating layer is disposed between the phase change material layer 13 and the second electrode 12. A specific disposition location of the heating layer is not limited in this application. The heating layer can improve a resistance of the entire unit, thereby improving the heating efficiency of the unit current.

When the adhesion layer is specifically disposed, the adhesion layer may be disposed between any two layers between the first electrode 11 and the second electrode 12. A specific disposition location of the adhesion layer is not limited in this application. The adhesion layer can improve an adhesion effect between two layers adjacent to the adhesion layer.

When the buffer layer is specifically disposed, the buffer layer may be disposed between any two layers between the first electrode 11 and the second electrode 12. A specific disposition location of the buffer layer is not limited in this application. The buffer layer can reduce mutual diffusion of two adjacent material layers in the phase change storage unit in repeated erase and write (or reset/set) operations, thereby improving reliability.

When the electrode layer is specifically disposed, the electrode layer may be disposed between any two layers between the first electrode 11 and the second electrode 12. A specific disposition location of the electrode layer is not limited in this application.

For example, materials of the heating layer, the adhesion layer, and the buffer layer may be, for example, oxide, a boron compound, a carbon compound, a nitrogen compound, a sulfur compound, and a halogen compound. The specific materials of the heating layer, the adhesion layer, and the buffer layer are not limited in this application, provided that corresponding functions of the material layers can be implemented.

Based on any one of the foregoing embodiments, the phase change storage unit may further include a gating material layer, and the gating material layer is located between the first electrode 11 and the second electrode 12. A specific disposition location of the gating material layer is not limited in this application. The gating material layer may be in a high resistance state at a low voltage, so as to suppress a leakage current, and may be in a low resistance state at a high voltage, so as to provide a sufficient current for read and write operations.

The gating material layer may include a single material layer, or may include a plurality of material layers. In an example, the gating material layer includes the single material layer. During specific implementation, the gating material layer may include a matrix material doped with a hafnium metal and/or a hafnium compound. The matrix material may be, for example, GeₓAs_{y}Se(Te)_{1-x-y}, where a sum of x and y is equal to 1. For the hafnium compound, refer to the related descriptions of the hafnium compound in the phase change material layer 13. Details are not described herein again. In another example, the gating material layer may include the plurality of material layers. During specific implementation, the gating material layer may include at least one hafnium-containing material layer and at least one sulfur compound material layer. For a specific implementation in which the gating material layer may include the plurality of material layers, refer to the related descriptions of the phase change material layer including the plurality of material layers. Details are not described herein again.

FIG. 11 is another schematic diagram of a structure of a phase change storage unit according to an embodiment of this application. A phase change storage unit 1 shown in FIG. 11 is a T-type phase change storage unit. As shown in FIG. 11, the phase change storage unit 1 includes a first electrode 11, a second electrode 12, and a phase change material layer 13 located between the first electrode 11 and the second electrode 12. The phase change storage unit 1 may 1 may further include a heating layer 16 located between the phase change material layer 13 and the second electrode 12, and an insulation layer 15 further wraps a side wall of the heating layer 16. The heating layer 16 needs to meet a conductive requirement, and further needs to improve a resistance effect of the entire phase change storage unit. The phase change material layer 13 is located on the heating layer 16 with a small cross section size and the insulation layer 15 that wraps the side wall of the heating layer 16. The phase change material layer 13 is connected to the second electrode 12 below the phase change material layer 13 by the conductive heating layer, and is also connected to the first electrode 11 above the phase change material layer 13. The first electrode 11 and the second electrode 12 extend in different horizontal directions to connect different phase change storage units in a storage array.

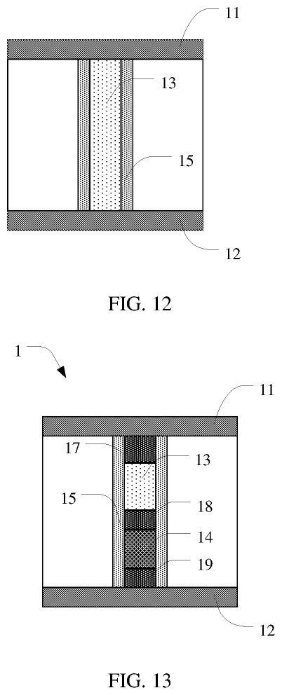

FIG. 12 is another schematic diagram of a structure of a phase change storage unit according to an embodiment of this application. A phase change storage unit 1 shown in FIG. 12 is a restrictive phase change storage unit. As shown in FIG. 12, the phase change storage unit 1 includes a first electrode 11, a second electrode 12, and a phase change material layer 13 located between the first electrode 11 and the second electrode 12. The phase change material layer 13 has a small cross section size, and is directly connected to the first electrode 11 above the phase change material layer 13 and the second electrode 12 below the phase change material layer 13. The phase change storage unit 1 may further include an insulation layer 15 located between the phase change material layer 13 and the second electrode 12, and the insulation layer 15 wraps a side wall of the phase change material layer 13.

FIG. 13 is another schematic diagram of a structure of a phase change storage unit according to an embodiment of this application. A phase change storage unit 1 shown in FIG. 13 is a three-dimensional phase change storage unit. As shown in FIG. 13, the phase change storage unit 1 includes a first electrode 11, a second electrode 12, and a phase change material layer 13 located between the first electrode 11 and the second electrode 12. The phase change material layer 13 may further include a gating material layer 14 located between the first electrode 11 and the second electrode 12. Cross section sizes of the phase change material layer 13 and the gating material layer 14 are small. A first electrode layer 17, the phase change material layer 13, a second electrode layer 18, the gating material layer 14, and a third electrode layer 19 are sequentially included between the first electrode 11 and the second electrode 12. The phase change material layer 13 may be connected to the first electrode 11 by the first electrode layer 17, and the gating material layer 14 may be connected to the phase change material layer 13 by the second electrode layer 18, and is connected to the second electrode 12 by the second electrode layer 18. The phase change storage unit 1 may further include an insulation layer 15 located between the phase change material layer 13 and the second electrode 12. The insulation layer 15 wraps the phase change material layer 13, the gating material layer 14, and side walls of the electrode layers. The first electrode 11 and the second electrode 12 extend in different horizontal directions, to connect different phase change storage units in a storage array to form an array arranged on one layer. Such arrays are further stacked in a vertical direction to form a cross-stacked three-dimensional phase change memory.

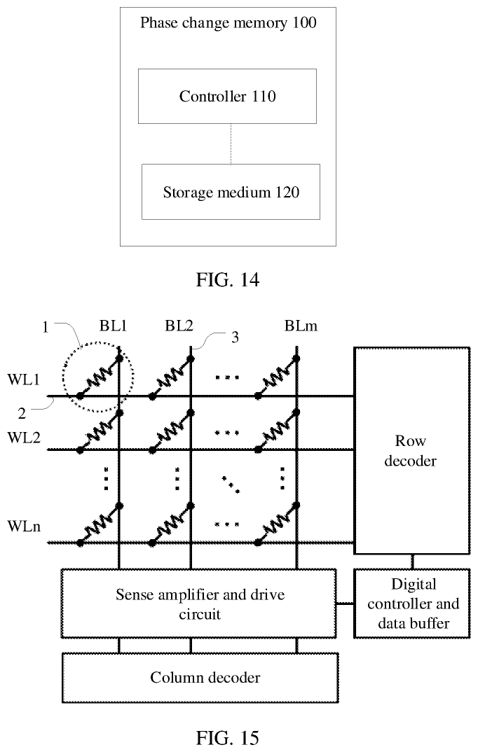

Based on a same invention concept, this application further provides a phase change memory. FIG. 14 is a schematic diagram of a structure of a phase change memory according to an embodiment of this application. As shown in FIG. 14, a phase change memory 100 includes a controller 110 and a storage medium 120. The storage medium 120 includes an array including the phase change storage unit 1 in any one of the foregoing embodiments.

Based on a same invention concept, this application further provides a phase change memory.

FIG. 15 is another schematic diagram of a structure of a phase change memory according to an embodiment of this application. As shown in FIG. 15, the phase change memory may further include a row decoder, a column decoder, a sense amplifier, a drive circuit, a data buffer, and a digital controller. First electrodes 12 of a plurality of phase change storage units 1 are connected to form a first electrode line 2, second electrodes 13 of the plurality of phase change storage units 1 are connected to form a second electrode line 3, and an extending direction of the first electrode line 2 intersects with an extending direction of the second electrode line 3. Specifically, there is a uniquely determined phase change storage unit 1 at an intersection of the first electrode line 2 and the second electrode line 3. The row decoder of the phase change memory is electrically connected to all first electrode lines 2, and the column decoder, the sense amplifier, and the drive circuit are electrically connected to all second electrode lines 3. The row decoder, the column decoder, the sense amplifier, and the drive circuit are electrically connected to the digital controller and the data buffer respectively. One of the first electrode line 2 and the second electrode line 3 is a word line (WL), and the other of the first electrode line 2 and the second electrode line 3 is a bit line (BL), so that one word line is connected to phase change storage units 1 in one row, and a level value different from that of another word line is applied to a selected word line, so as to select phase change storage units 1 in a row to perform read and write operations and the like. One bit line is connected to phase change storage units 1 in one column, and transmits an electrical signal of a write operation of the phase change storage unit 1 to a column selected by the column decoder, or transmits, along a selected column, an electrical signal obtained by an operation of a reading unit to the column decoder. Specifically, the first electrode line 2 may be used as the word line, and the second electrode line 3 may be used as the bit line; or the first electrode line 2 may be used as the bit line, and the second electrode line 3 may be used as the word line. This is not limited in this application.

The following describes a working process of the phase change memory in the technical solutions of this application by using an example in which the first electrode line 2 is the word line and the second electrode line 3 is the bit line. The row decoder of the phase change memory is electrically connected to all the first electrode lines 2, and the column decoder, the sense amplifier, and the drive circuit are electrically connected to all the second electrode lines 3. The row decoder, the column decoder, the sense amplifier, and the drive circuit are electrically connected to the digital controller and the data buffer respectively. Because there is a uniquely determined phase change storage unit 1 located at an intersection of the first electrode line 2 and the second electrode line 3, and the phase change storage unit 1 has different resistance states, read and write operations of a three-dimensional phase change memory can be implemented. When a read operation is performed, the digital controller controls the row decoder to modulate a voltage of the first electrode line 2 connected to a set phase change storage unit 1 to a read mode (for example, a voltage is 0V), and controls the column decoder to modulate a voltage of the second electrode line 3 connected to the set phase change storage unit 1 to the read mode (for example, a voltage is 1V). Then, a current of the set phase change storage unit 1 is measured by using the sense amplifier connected to the second electrode line 3, to determine a resistance state of a phase change material layer 13 of the phase change storage unit 1, so as to obtain a data storage state. When a write operation is performed, the digital controller controls the row decoder to modulate the voltage of the first electrode line 2 connected to the set phase change storage unit 1 to a write mode (for example, a voltage is 2V), and controls the column decoder to modulate the voltage of the second electrode line 3 connected to the set phase change storage unit 1 to the write mode (for example, a voltage is 0V), and then a write pulse current or pulse voltage is sent to the set phase change storage unit 1 by using the drive circuit connected to the second electrode line 3, to change a resistance state of the phase change storage unit 1, to implement the write operation. In addition, data read from the sense amplifier and data written to the phase change memory are stored in the data buffer.

In a specific embodiment, refer to FIG. 15. The phase change memory may be a two-dimensional phase change memory. In a specific embodiment, the phase change storage units 1 in the two-dimensional phase change memory may be arranged in an array, for example, may be arranged in n rows and m columns, where m and n are respectively positive integers greater than 1.

The foregoing descriptions are merely specific implementations of this application, but are not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims.

What is claimed is:

1. A phase change material, wherein the phase change material comprises a hafnium-containing material, the hafnium-containing material is formed by doping hafnium-containing or a hafnium-containing compound to a parent material, and the parent material comprises a compound that is formed by tellurium and at least one of germanium, antimony, and bismuth and that can perform a phase change.

2. The phase change material according to claim 1, wherein the phase change material further comprises a sulfur compound material, and the sulfur compound material is located above or below the hafnium-containing material.

3. The phase change material according to claim 2, wherein the phase change material comprises a plurality of phase change material units that are superposed together, and each phase change material unit comprises one layer of the hafnium-containing material and one layer of the sulfur compound material.

4. The phase change material according to claim 1, wherein atomic percentages of different parts of the hafnium-containing or the hafnium-containing compound in the phase change material are inconsistent.

5. The phase change material according to claim 4, wherein when the phase change material is located between a top electrode and a bottom electrode, the atomic percentages of the hafnium-containing or the hafnium-containing compound in the phase change material are in a gradient change from high to low or from low to high in a direction from the top electrode to the bottom electrode.

6. The phase change material according to claim 1, wherein in the hafnium-containing material, an atomic percentage of the hafnium and/or the hafnium compound is 0.1% to 40%.

7. The phase change material according to claim 1, wherein in the hafnium-containing material, the atomic percentage of the hafnium and/or the hafnium compound is 1.5% to 6.5%, 10% to 19.5%, 25% to 35%, 7% to 14%, 17% to 24%, or 27% to 34%.

8. The phase change material according to claim 1, wherein the parent material comprises any one of the following materials: GexSbyTe1−x−y and GexBiyTe1−x−y, wherein a value range of a sum of x and y is greater than 0 and less than 100%, or the parent material further comprises SbxTey, or the parent material further comprises GexSbyBizTe1−x−y−z, wherein a sum of x, y, and z is 100%.

9. The phase change material according to claim 8, wherein in the materials GexSbyTe1−x−y and GexBiyTe1−x−y, x:y:(1−x−y)=4:1:5, 2:2:5, 3:2:6, 1:2:4, or 1:4:7, and in the material SbxTey, x:y=2:3, 1:1, 2:1, or 1:0.

10. The phase change material according to claim 8, wherein in GexSbyTe1−x−y, 1/7−1/10≤x:(1−x−y)≤1/4+1/10, or 2/3−1/10≤y:(1−x−y)≤2/3+1/10, or 1/7≤x:(1−x−y)≤2/5, or 2/3≤y:(1−x−y)≤4.

11. The phase change material according to claim 1, wherein the hafnium compound comprises at least one of the following: a hafnium metal oxide, a hafnium metal boride, a hafnium metal carbide, a hafnium metal nitrogen compound, a hafnium metal sulfur compound, a hafnium metal halogen compound, and a binary or multi-ary compound formed by a hafnium metal and another metal.

12. A storage chip, wherein the storage chip comprises a plurality of storage units, and each storage unit comprises the phase change material, the phase change material comprises a hafnium-containing material, the hafnium-containing material is formed by doping hafnium-containing or a hafnium-containing compound to a parent material, and the parent material comprises a compound that is formed by tellurium and at least one of germanium, antimony, and bismuth and that can perform a phase change.

13. The storage chip according to claim 12, wherein the phase change material further comprises a sulfur compound material, and the sulfur compound material is located above or below the hafnium-containing material.

14. The storage chip according to claim 12, wherein the phase change material comprises a plurality of phase change material units that are superposed together, and each phase change material unit comprises one layer of the hafnium-containing material and one layer of the sulfur compound material.

15. The storage chip according to claim 12, wherein atomic percentages of different parts of the hafnium-containing or the hafnium-containing compound in the phase change material are inconsistent.

16. The storage chip according to claim 15, wherein when the phase change material is located between a top electrode and a bottom electrode, the atomic percentages of the hafnium-containing or the hafnium-containing compound in the phase change material are in a gradient change from high to low or from low to high in a direction from the top electrode to the bottom electrode.

17. The storage chip according to claim 12, wherein in the hafnium-containing material, an atomic percentage of the hafnium and/or the hafnium compound is 0.1% to 40%.

18. The storage chip according to claim 12, wherein in the hafnium-containing material, the atomic percentage of the hafnium and/or the hafnium compound is 1.5% to 6.5%, 10% to 19.5%, 25% to 35%, 7% to 14%, 17% to 24%, or 27% to 34%.

19. The storage chip according to claim 12, wherein each storage unit further comprises a gating material, and the gating material is doped with hafnium or a hafnium compound.

20. A phase change memory, comprising a controller and at least one storage chip according to claim 12, wherein the controller is configured to store data to the at least one storage chip, or read data from the at least one storage chip.
